(19) United States
(12) Patent Application Publication
(10) Pub. No.: US 2017/0092661 A1
(43) Pub. Date: Mar. 30, 2017

(54) THIN FILM TRANSISTOR, ARRAY SUBSTRATE AND MANUFACTURING METHOD THEREOF, AND DISPLAY DEVICE

(71) Applicant: BOE TECHNOLOGY GROUP CO., LTD., Beijing (CN)

(72) Inventor: Xiaming ZHU, Beijing (CN)

(21) Appl. No.: 15/159,385

(22) Filed: May 19, 2016

(30) Foreign Application Priority Data
Sep. 30, 2015 (CN) 201510640168.3

(51) Int. Cl. H01L 27/12; H01L 29/417; H01L 29/66; H01L 29/49; H01L 29/24; H01L 29/786; H01L 29/15; H01L 29/423

(52) U.S. Cl. CPC H01L 27/1225; H01L 29/158; H01L 27/127; H01L 29/41733; H01L 29/42384; H01L 29/4908; H01L 29/24; H01L 29/7869; H01L 29/78696; H01L 29/66969

(57) ABSTRACT

The present invention provides a thin film transistor comprising an active layer, the active layer has a superlattice structure, and comprises a plurality of semiconductor layers and an insulating layer between every two adjacent semiconductor layers, a thickness of each of the semiconductor layers and the insulating layers is in nanometer range, and the plurality of semiconductor layers are made of at least one of metal oxide semiconductor and metal nitride oxide semiconductor. The present invention further provides an array substrate and a manufacturing method thereof, and a display device. The thin film transistor has excellent electrical characteristics and reliability, such as higher carrier mobility, lower turn-off leak current and better stability of threshold voltage.

### FIELD OF THE INVENTION

The present invention relates to the field of display technology, in particular to a thin film transistor, an array substrate comprising the thin film transistor, a manufacturing method of the array substrate, and a display device comprising the array substrate.

### BACKGROUND OF THE INVENTION

For improving the carrier mobility in an active layer of a thin film transistor, the active layer of the thin film transistor can be made of superlattice materials. In prior art, there is a type of thin film transistor in which an active layer has a superlattice structure formed by stacking three semiconductor layers, and this type of thin film transistor has high carrier mobility and good stability.

However, in the active layer with the above superlattice structure, the movement of carriers is limited by defect states occurring at the interfaces between different semiconductor layers, which limits further improvement of the carrier mobility to some extent.

Therefore, an urgent technical problem to be solved is how to further improve the carrier mobility of the thin film transistor with active layer made of superlattice materials.

### SUMMARY OF THE INVENTION

An object of the present invention is to provide a thin film transistor, an array substrate comprising the thin film transistor, a manufacturing method of the array substrate, and a display device comprising the array substrate. An active layer of the thin film transistor has a superlattice structure, and has high carrier mobility and good stability.

To achieve the above object, as an aspect of the present invention, a thin film transistor is provided, the thin film transistor comprises an active layer, wherein the active layer has a superlattice structure, and comprises a plurality of semiconductor layers and an insulating layer between every two adjacent semiconductor layers, a thickness of each of the semiconductor layers and the insulating layers is in nanometer range, and the plurality of semiconductor layers are made of at least one of metal oxide semiconductor and metal nitride oxide semiconductor.

Preferably, the thickness of each semiconductor layer is no more than 10 nm, and/or the thickness of each insulating layer is no more than 3 nm.

Preferably, the active layer further comprises an insulating layer located above the semiconductor layer at the uppermost layer.

Further, the active layer further comprises an insulating layer located below the semiconductor layer at the lowermost layer.

Preferably, the insulating layers are made of any one of SiO₂, HfO₂, TiO₂, ZrO₂, Y₂O₃, La₂O₃ and Ta₂O₅.

Preferably, the metal oxide semiconductor is any one of a single metal oxide semiconductor, a ternary metal oxide semiconductor and a quaternary metal oxide semiconductor.

Preferably, the single metal oxide semiconductor is any one of ZnO, In₂O₃, SnO₂, and Ga₂O₃; the ternary metal oxide semiconductor is any one of In—Zn—O, In—Ga—O, Zn—Sn—O, In—Sn—O and In—W—O; and the quaternary metal oxide semiconductor is any one of In—Ga—Zn—O, In—Sn—Zn—O and Hf—In—Zn—O.

Preferably, the metal nitride oxide semiconductor is any one of a single metal nitride oxide semiconductor, a quaternary metal nitride oxide semiconductor and a quinary metal nitride oxide semiconductor.

Preferably, the single metal nitride oxide semiconductor is any one of ZnOₓN_{y}, InOₓN_{y}, SnOₓN_{y} and GaOₓN_{y}; the quaternary metal nitride oxide semiconductor is any one of InZnOₓN_{y}, InGaOₓN_{y}, ZnSnOₓN_{y}, InSnOₓN_{y} and InWOₓN_{y}; and the quinary metal nitride oxide semiconductor is any one of InGaZnOₓN_{y}, InSnZnOₓN_{y} and HfInZnOₓN_{y}.

Preferably, the thin film transistor further comprises a source, a drain and a passivation layer, the source and the drain are electrically connected to the active layer at a left side and a right side of the active layer, respectively, and the passivation layer covers the source and the drain.

In this situation, the thin film transistor may further comprise an etch stop layer provided above the active layer, wherein the source and the drain are provided above the etch stop layer, and electrically connected to the active layer through via holes penetrating through the etch stop layer at the left side and the right side of the active layer, respectively.

Preferably, the thin film transistor further comprises a source, a drain, a gate, a gate insulating layer and a passivation layer, wherein the source and the drain are electrically connected to the active layer at the left side and the right side of the active layer, respectively, the gate is located above the active layer, the gate insulating layer is provided between the gate and the active layer, and the passivation layer covers the gate.

In this situation, the thin film transistor may further comprise an etch stop layer provided above the active layer, wherein the source and the drain are provided above the etch stop layer, and electrically connected to the active layer through via holes penetrating through the etch stop layer at the left side and the right side of the active layer, respectively.

Preferably, the active layer comprises a semiconductor region, and two conductive regions at a left side and a right side of the semiconductor region respectively, the conductive regions are formed by processing materials for forming the active layer with plasma, the thin film transistor comprises a source, a drain, a gate, a gate insulating layer and an interlayer insulating layer, the gate insulating layer is provided on the semiconductor region, the gate is provided on the gate insulating layer, the interlayer insulating layer covers the gate and the active layer, and the source and the drain are located above the two conductive regions and electrically connected to the conductive regions through via holes penetrating through the interlayer insulating layer, respectively.

In this situation, the thin film transistor may further comprise a passivation layer covering the source, the drain and the interlayer insulating layer, and a pixel electrode electrically connected to the drain through a via hole penetrating through the passivation layer.

As another aspect of the present invention, an array substrate is provided, the array substrate is divided into a plurality of display units, and each of the display units is provided with the above thin film transistor provided in the present invention.

As a still another aspect of the present invention, a manufacturing method of the above array substrate provided in the present invention is provided, and the manufacturing method comprises a step for forming the active layer, wherein the step for forming the active layer comprise steps for forming each of the semiconductor layers and steps for forming each of the insulating layers between every two adjacent semiconductor layers.

Preferably, the semiconductor layers and each of the insulating layers between every two adjacent semiconductor layers are formed by sputtering processes in a single vacuum environment.

Since the active layer has a superlattice structure comprising a plurality of semiconductor layers and an insulating layer between every two adjacent semiconductor layers, the thickness of each of the semiconductor layers and the insulating layers is small and in nanometer range, the quantum effect of the carriers in the semiconductor layers are limited in a two-dimensional plane, therefore, the carriers has high mobility.

In a preferable embodiment of the present invention, the active layer further comprises an insulating layer located above the semiconductor layer at the uppermost layer and an insulating layer located below the semiconductor layer at the lowermost layer; at this time, an insulating layer is formed at both a top interface and a bottom interface of each of the semiconductor layers so as to reduce the occurrence of defect states at the interfaces between different semiconductor layers. The insulating layer at the outmost side of the active layer with a superlattice structure plays a protection function to prevent the active layer from being impacted by the outside factors, so as to maintain the stability of material property, and it can be used to achieve an oxide thin film transistor of back channel etching structure. The thicknesses of the insulating layers are small and in nanometers, there is a certain probability that the carriers moving in a semiconductor layer tunneling to adjacent semiconductor layers, and the carriers from two semiconductor layers converge at a source region or a drain region to achieve large current transmission.

In summary, in comparison with the thin film transistor with an active layer having a superlattice structure in prior art, the thin film transistor provided in the present invention has higher carrier mobility and better electrical stability of devices, and can achieve a smaller oxide thin film transistor of back channel etching structure.

As a further aspect of the present invention, a display device is provided, and the display device comprises the above array substrate provided in the present invention.

### BRIEF DESCRIPTION OF THE DRAWINGS

The accompanying drawings which constitute a part of the description are used for providing further understanding of the present invention and for explaining the present invention in conjunction with the following specific embodiments, rather than limiting the present invention. In the accompanying drawings:

FIG. 1 is a diagram of a thin film transistor according to a first embodiment of the present invention;

FIG. 2 is a diagram of an active layer of the thin film transistor shown in FIG. 1;

FIG. 3 is a diagram of a thin film transistor according to a second embodiment of the present invention;

FIG. 4 is a diagram of a thin film transistor according to a third embodiment of the present invention;

FIG. 5 is a diagram of a thin film transistor according to a forth embodiment of the present invention; and

FIG. 6 is a diagram of a thin film transistor according to a fifth embodiment of the present invention.

### REFERENCE NUMERALS

100: active layer 100a: first semiconductor layer

| | |
|---|---|
| 100b: second semiconductor layer | 100c: first insulating layer |
| 100d: second insulating layer | 100e: third insulating layer |
| 210: source | 220: drain |
| 300: gate | 400: gate insulating layer |
| 500: etch stop layer | 600: pixel electrode |
| 700: passivation layer | 410: interlayer insulating layer |

### DETAILED DESCRIPTION OF THE EMBODIMENTS

Hereinafter, specific embodiments of the present invention will be described in detail with reference to the accompanying drawings. It should be understood that the embodiments described herein are only employed for illustrating and explaining the present invention, rather than limiting the present invention.

In the present invention, the locality nouns of “above” and “below” all refer to the directions of “up” and “down” in FIGS. 1-6.

As an aspect of the present invention and as shown in FIG. 1, a thin film transistor is provided, the thin film transistor comprises an active layer 100, wherein the active layer 100 has a superlattice structure, and comprises a plurality of semiconductor layers and an insulating layer between every two adjacent semiconductor layers, that is, the semiconductor layers and the insulating layers are stacked alternately, the thickness of each of the semiconductor layers and the insulating layers is in nanometer range, and the semiconductor layers are made of metal oxide semiconductor or metal nitride oxide semiconductor.

Because the active layer 100 has a superlattice structure formed by stacking the semiconductor layers and the insulating layers alternately, and the thickness of each of the semiconductor layers and the insulating layers is in nanometer range, the quantum effect of the carriers in the semiconductor layers are limited in a two-dimensional plane, therefore, the carriers has high mobility. Moreover, since the thickness of each of the insulating layers is also in nanometer range, when a voltage is applied between a source 210 and a drain 220 of the thin film transistor, the carriers in the semiconductor layers can tunneling to adjacent insulating layers, so as to form a continuous current between the source 210 and the drain 220.

It should be explained that “the active layer 100 comprises a plurality of semiconductor layers and an insulating layer between every two adjacent semiconductor layers” means when the active layer comprises two semiconductor layers, the active layer further comprises an insulating layer between the two adjacent semiconductor layers; when the active layer comprises three or more semiconductor layers, the active layer further comprises two or more insulating layer between every two adjacent semiconductor layers. In summary, it should be ensured that an insulating layer is provided between every two adjacent semiconductor layers. It should be noted that, when being used for achieving an oxide thin film transistor of back channel etching structure, the active layer with superlattice structure must further comprise an insulating layer located above the semiconductor layer at the uppermost layer. In addition, the thickness of each material layer in the active layer with superlattice structure is very small, and therefore, the active layer with superlattice structure is formed by stacking a plurality of semiconductor layers and a plurality of insulating layers alternately.

As an embodiment of the present invention, an active layer 100 may comprise two semiconductor layers and an insulating layer between the two adjacent semiconductor layers. Specifically, the semiconductor layers may comprise a first semiconductor layer 100a and a second semiconductor layer 100b, the insulating layer may comprise a first insulating layer 100c provided between the first semiconductor layer 100a and the second semiconductor layer 100b.

In the present invention, the first semiconductor layer 100a may be a metal oxide semiconductor or a metal nitride oxide semiconductor; similarly, the second semiconductor layer 100a may be a metal oxide semiconductor or a metal nitride oxide semiconductor.

The metal oxide semiconductor has high carrier mobility and excellent current turn-off property, and the metal nitride oxide semiconductor has high carrier mobility. In order to integrate the advantages of the metal oxide semiconductor and the metal nitride oxide semiconductor, preferably, one of the first semiconductor layer 100a and the second semiconductor layer 100b is made of the metal oxide semiconductor and the other is made of the metal nitride oxide semiconductor.

In the present invention, as a simplest implementation model, the active layer 100 may comprise only the first semiconductor layer 100a, the second semiconductor layer 100b and the first insulating layer 100c.

Preferably, the active layer comprises a plurality of insulating layers, and an insulating layer is formed above the semiconductor layer at the uppermost layer. When manufacturing the active layer with superlattice structure of the thin film transistor, each film layer is formed sequentially from bottom to top. The active layer is a key layer directly influencing the device characteristics of the thin film transistor. Although the active layer with superlattice structure comprises a plurality of film layers stacked alternately, the plurality of film layers are formed sequentially in a single vacuum environment. A passivation process can be performed to a top interface and a bottom interface of each of the semiconductor layers through providing insulating layers on the top side and the bottom side of each of the semiconductor layers so as to reduce the occurrence of defect states at the interfaces between different semiconductor layers; moreover, the uppermost insulating layer and the lowermost insulating layer can seal the whole superlattice structure to protect the active layer and prevent it from being effected by outside influences so as to keep the material property of the active layer stable; in addition, the top side and the bottom side of each of the semiconductor layers are provided with a thin insulating layer for passivation protection. It can be seen that the thin film transistor comprising an active layer with superlattice structure provided in the present invention has not only high carrier mobility, but good electrical stability and low leak current, and the threshold voltage of the thin film transistor can be controlled around 0V, which reduces logic energy consumption of devices.

Specifically, the active layer further comprises a second insulating layer 100d provided below a lower one of the first semiconductor layer 100a and the second semiconductor layer 100b.

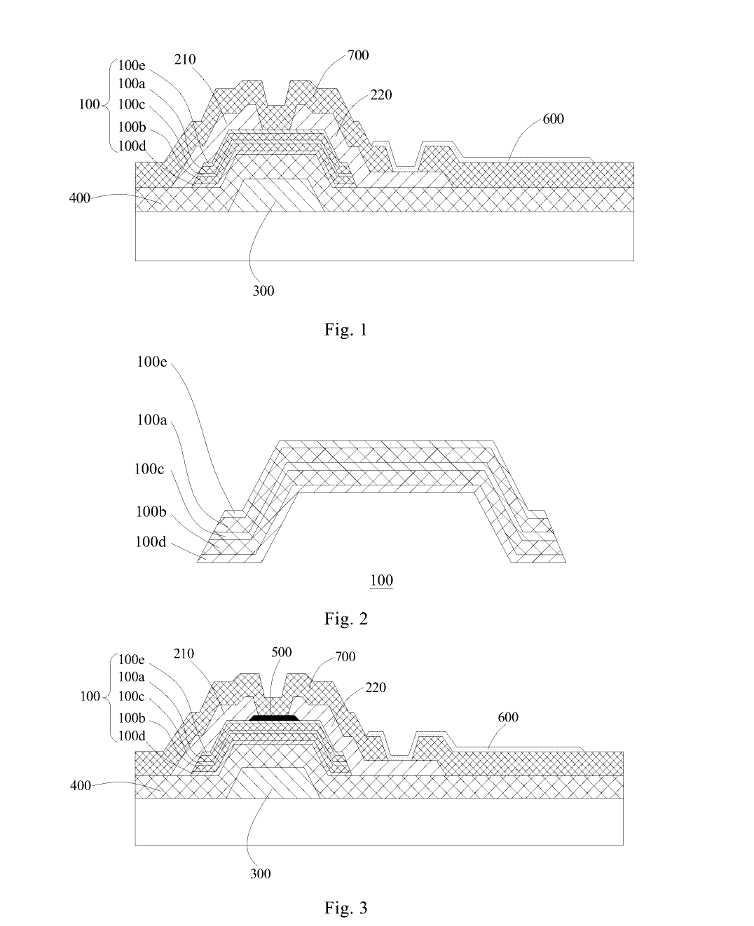

In order to reduce the occurrence of defect states at the lower surface of the lower one of the first semiconductor layer 100a and the second semiconductor layer 100b, it is preferable to first form a thin second insulating layer 100d in the active layer with superlattice structure, and then form the lower one of the first semiconductor layer 100a and the second semiconductor layer 100b. As shown in FIG. 2, the second semiconductor layer 100b is located below the first semiconductor layer 100a, therefore, the second insulating layer 100d is located below the second semiconductor layer 100b. Arranging the second insulating layer 100d can reduce the occurrence of defect states at the interface between second semiconductor layer 100b and the gate insulating layer 400 of the thin film transistor as shown in FIGS. 1 and 3, so as to cause the electric characteristics of the oxide thin film transistor to be more stable.

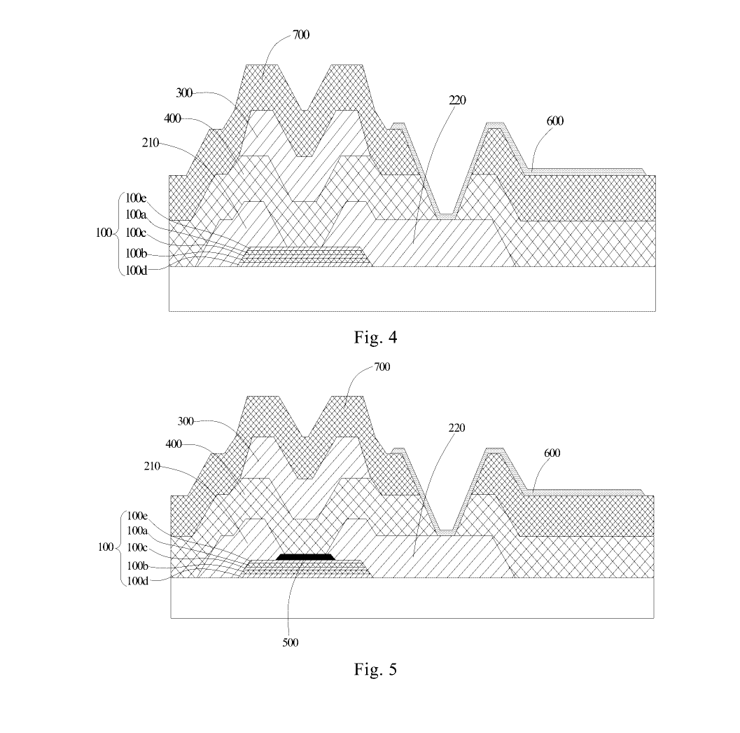

The thin film transistor provided in the present invention can be a thin film transistor with back channel etching structure or etch stop structure. When the thin film transistor is a thin film transistor with back channel etching structure (as shown in FIGS. 1 and 4), the thin film transistor comprises no etch stop layer, at this time, the thin film transistor further comprises a third insulating layer 100e provided above a upper one of the first semiconductor layer 100a and the second semiconductor layer 100b so as to prevent the semiconductor layers from being damaged by the consequent etching process for forming the source and the drain. In order to ensure the carriers in the active layer to reach the source and the drain by quantum tunneling effect, a thickness of the third insulating layer 100e is no more than 3 nm. The thin film transistor in the preferable embodiment of the present invention is a back channel etching structure to reduce the size of the thin film transistor so as to improve an aperture ratio of the array substrate comprising the thin film transistor and achieve high resolution displaying.

FIG. 2 shows an enlarged diagram of the active layer 100 shown in FIG. 1. The active layer comprises a second insulating layer 100d, a second semiconductor layer 100b, a first insulating layer 100c, a first semiconductor layer 100a and a third insulating layer 100e stacked from bottom to top. Both sides of each of the semiconductor layers in the active layer with superlattice structure are provided with an insulating layer for passivation protection to reduce the occurrence of defect states at the interfaces between the semiconductor layers, which can enhance the electrical stability of the thin film transistor devices. In addition, the third insulating layer 100e protects the uppermost semiconductor layer functioning as an electric conductor in the active layer with superlattice structure and prevent the semiconductor layer from being impacted by the consequent etching process for forming the source and the drain, therefore, the active layer can be used to achieve an oxide thin film transistor with back channel etching structure.

For better passivating the defect states at the interface between the first semiconductor layer 100a and the second semiconductor layer 100b, and for avoiding introduction of impurity of hydrogen atoms which can easily form donors in an oxide semiconductor, preferably, the insulating layers are formed through a sputtering process. The insulating layers are made of any one of SiO₂, HfO₂, TiO₂, ZrO₂, Y₂O₃, La₂O₃ and Ta₂O₅.

In the present invention, in order to constrain the carriers of the active layer in a two-dimensional plane so as to improve mobility, the active layer uses a superlattice structure formed by stacking the semiconductor layers and the insulating layer alternately, and preferably, the thickness of each semiconductor layer is no more than 10 nm.

In the present invention, there are no special requirements for types of the metal oxide semiconductor for forming the first semiconductor layer 100a or the second semiconductor layer 100b. For example, the metal oxide semiconductor is any one of a single metal oxide semiconductor, a ternary metal oxide semiconductor and a quaternary metal oxide semiconductor.

Specifically, the single metal oxide semiconductor is any one of ZnO, In₂O₃, SnO₂, and Ga₂O₃; the ternary metal oxide semiconductor is any one of In—Zn—O, In—Ga—O, Zn—Sn—O, In—Sn—O and In—W—O; and the quaternary metal oxide semiconductor is any one of In—Ga—Zn—O, In—Sn—Zn—O and Hf—In—Zn—O, wherein the symbol of “-” means there is no specific ratio for each element in the material.

In the present invention, there are no special requirements for types of the metal nitride oxide semiconductor for forming the first semiconductor layer 100a or the second semiconductor layer 100b. For example, the metal nitride oxide semiconductor is any one of a single metal nitride oxide semiconductor, a quaternary metal nitride oxide semiconductor and a quinary metal nitride oxide semiconductor

Specifically, the single metal nitride oxide semiconductor is any one of ZnOₓN_{y}, InOₓN_{y}, SnOₓN_{y} and GaOₓN_{y}; the quaternary metal nitride oxide semiconductor is any one of InZnOₓN_{y}, InGaOₓN_{y}, ZnSnOₓN_{y}, InSnOₓN_{y} and InWOₓN_{y}; and the quinary metal nitride oxide semiconductor is any one of InGaZnOₓN_{y}, InSnZnOₓN_{y} and HfInZnOₓN_{y}.

As described above, the thin film transistor provided in the present invention can also be a thin film transistor with etch stop structure. Specifically, as shown in FIGS. 3 and 5, the thin film transistor further comprises an etch stop layer 500 provided above the active layer 100, wherein the source 210 and the drain 220 are provided above the etch stop layer 500 and electrically connected to the active layer 100 through via holes penetrating through the etch stop layer at a left side and a right side of the active layer 100 respectively. The thin film transistor as shown in FIG. 3 has a bottom-gate structure, and a gate 300 is located below the active layer 100; the thin film transistor as shown in FIG. 5 has a top-gate structure, and a gate 300 is located above the active layer 100. A gate insulating layer 400 is provided between the gate 300 and the active layer 100.

The etch stop layer 500 is made of any one of SiO₂, HfO₂, TiO₂, ZrO₂, Y₂O₃, La₂O₃ and Ta₂O₅. The etch stop layer 500 can protect the active layer 100 and prevent it from being damaged by etching during the consequent wet etching process for forming the source 210 and the drain 220.

As shown in FIGS. 1 and 4, the thin film transistor further comprises a source 210, a drain 220, a passivation layer 700 and a pixel electrode 600, the source 210 and the drain 220 are electrically connected to the active layer 100 at a left side and a right side of the active layer 100 respectively, and the passivation layer 700 covers the source 210 and the drain 220.

The gate of the thin film transistor of self-aligned top-gate structure has no overlapped area with the source and the drain, and this type of thin film transistor has the advantage of small parasitic capacitance. In this type of thin film transistor, a channel region of the thin film transistor is determined by a pattern of the gate, in order to reduce a series resistance between the source 210 and the drain 220 and the active layer 100, an area of active layer not covered by the gate is processed to have conductive function. Preferably, the active layer comprises a semiconductor region B, and two conductive regions A at both sides of the semiconductor region B respectively, the conductive regions A are formed by processing materials for forming the active layer 100 with plasma, and the source 210 and the drain 220 are electrically connected to the two conductive regions A located at a left side and a right side of the semiconductor region B respectively through via holes penetrating through an interlayer insulating layer 410 respectively

It should be explained that the conductive regions A also has a superlattice structure comprising a plurality of semiconductor layers and an insulating layer between every two adjacent semiconductor layers.

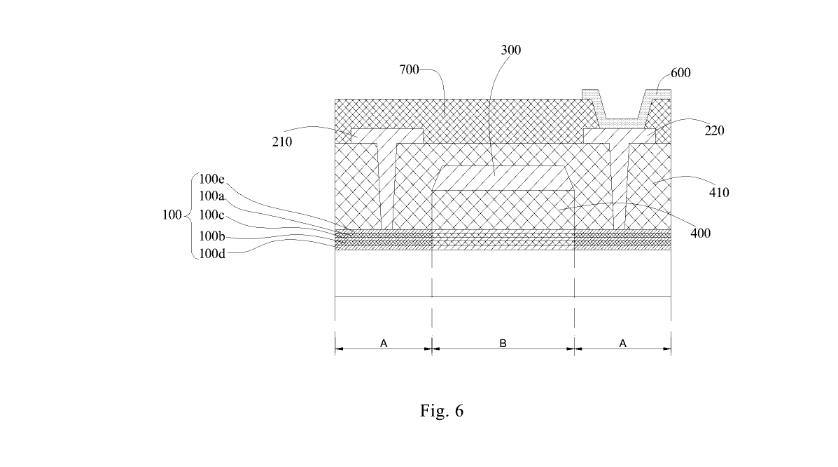

FIG. 6 is a diagram of a thin film transistor of self-aligned top-gate structure. As shown in FIG. 6, the thin film transistor further comprises a gate 300, a gate insulating layer 400 and an interlayer insulating layer 410, the gate insulating layer 400 is provided on the semiconductor region B, the gate 300 is provided on the gate insulating layer 400, the interlayer insulating layer 410 covers the gate 300 and the active layer 100. The source 210 and the drain 220 are located above the two conductive regions A respectively and electrically connected to the conductive regions A through via holes penetrating through the interlayer insulating layer 410 respectively.

It can be seen from FIG. 6 that the pattern of the gate insulating layer 400, the pattern of the semiconductor region B are the same as that of the gate 300. The practical process is taking the pattern of the gate 300 as a mask. When forming the pattern of the gate insulating layer 400 through dry plasma etching process, the areas of the active layer except the semiconductor region B is processed by the plasma to form the conductive regions A.

It is easy to understand that the thin film transistor further comprises a pixel electrode 600 electrically connected to the drain 220, moreover, the thin film transistor further comprises a passivation layer 700. In embodiments shown in FIGS. 1, 3 and 6, the passivation layer 700 covers the source and the drain, and the pixel electrode 600 is electrically connected to the drain 220 through a via hole penetrating through the passivation layer 700. In embodiments shown in FIGS. 4 and 5, the passivation layer 700 covers the gate, and the pixel electrode 600 is electrically connected to the drain 220 through a via hole penetrating through the passivation layer 700 and the gate insulating layer 400.

As another aspect of the present invention, an array substrate is provided, the array substrate is divided into a plurality of display units, and each of the display units is provided with the above thin film transistor provided in the present invention

Because the thin film transistor has high carrier mobility and good electrical stability, the array substrate also has good electrical characteristics.

As a still another aspect of the present invention, a manufacturing method of an array substrate is provided. Specifically, the method for manufacturing the above array substrate provided in the present invention comprises a step for forming the active layer, wherein the step for forming the active layer comprise steps for forming each of the semiconductor layers and steps for forming each of the insulating layers between every two adjacent semiconductor layers.

Preferably, the semiconductor layers and each of the insulating layers between every two adjacent semiconductor layers are formed by a sputtering process in a single vacuum environment. When manufacturing the active layer with the manufacturing method provided in the present invention, the superlattice structure formed by stacking the insulating layers and the semiconductor layers in a single vacuum environment can be achieved by arranging a plurality of target materials in a single vacuum environment, thus improving the efficiency of manufacturing the array substrate. Moreover, since the thickness of each of the insulating layers and the semiconductor layers is in nanometer range, the process of forming the active layer in a single vacuum environment can reduce the occurrence of defect states at the interface between the insulating layer and the semiconductor layers, and ensure the obtained superlattice material has excellent electrical characteristic.

It is easy to understand that the manufacturing method further comprises steps for forming a pattern of the active layer, forming a pattern of the gate, forming a pattern of the gate insulating layer, forming patterns of the source and the drain, forming the interlayer insulating layer, forming the passivation layer, forming a pattern of the pixel electrode, and so on, thus finally obtaining a complete thin film transistor array substrate.

As a further aspect of the present invention, a display device is provided, and the display device comprises the above array substrate provided in the present invention.

The display device may be a liquid crystal display device or an OLED display device. The display device may be a computer display, a tablet PC, a mobile phone, a navigator or any other electronic equipment.

It should be understood that the above embodiments are only exemplary embodiments for illustrating the principle of the present invention, but the present invention is not limited thereto. Various variations and improvements can be made by the person of ordinary skill in the art without departing from the spirit and essence of the present invention, and these variations and improvements should also be considered to fall within the protection scope of the present invention.

1. A thin film transistor, comprising an active layer, wherein
the active layer has a superlattice structure, and comprises a plurality of semiconductor layers and an insulating layer between every two adjacent semiconductor layers, a thickness of each of the semiconductor layers and the insulating layers is in nanometer range, and the plurality of semiconductor layers are made of at least one of metal oxide semiconductor and metal nitride oxide semiconductor.

2. The thin film transistor according to claim 1, wherein the thickness of each semiconductor layer is no more than 10 nm, and/or the thickness of each insulating layer is no more than 3 nm.

3. The thin film transistor according to claim 1, wherein the active layer further comprises an insulating layer located above the semiconductor layer at the uppermost layer.

4. The thin film transistor according to claim 3, wherein the active layer further comprises an insulating layer located below the semiconductor layer at the lowermost layer.

5. The thin film transistor according to claim 1, wherein the insulating layers are made of any one of SiO₂, HfO₂, TiO₂, ZrO₂, Y₂O₃, La₂O₃ and Ta₂O₅.

6. The thin film transistor according to claim 1, wherein the metal oxide semiconductor is any one of a single metal oxide semiconductor, a ternary metal oxide semiconductor and a quaternary metal oxide semiconductor.

7. The thin film transistor according to claim 6, wherein
the single metal oxide semiconductor is any one of ZnO, In₂O₃, SnO₂, and Ga₂O₃;
the ternary metal oxide semiconductor is any one of In—Zn—O, In—Ga—O, Zn—Sn—O, In—Sn—O and In—W—O; and
the quaternary metal oxide semiconductor is any one of In—Ga—Zn—O, In—Sn—Zn—O and Hf—In—Zn—O.

8. The thin film transistor according to claim 1, wherein the metal nitride oxide semiconductor is any one of a single metal nitride oxide semiconductor, a quaternary metal nitride oxide semiconductor and a quinary metal nitride oxide semiconductor.

9. The thin film transistor according to claim 8, wherein
the single metal nitride oxide semiconductor is any one of ZnOₓN_{y}, InOₓN_{y}, SnOₓN_{y} and GaOₓN_{y};
the quaternary metal nitride oxide semiconductor is any one of InZnOₓN_{y}, InGaOₓN_{y}, ZnSnOₓN_{y}, InSnOₓN_{y} and InWOₓN_{y}; and
the quinary metal nitride oxide semiconductor is any one of InGaZnOₓN_{y}, InSnZnOₓN_{y} and HfInZnOₓN_{y}.

10. The thin film transistor according to claim 3, further comprising a source, a drain and a passivation layer, the source and the drain are electrically connected to the active layer at a left side and a right side of the active layer, respectively, and the passivation layer covers the source and the drain.

11. The thin film transistor according to claim 1, further comprising a source, a drain and a passivation layer, the source and the drain are electrically connected to the active layer at a left side and a right side of the active layer, respectively, and the passivation layer covers the source and the drain.

12. The thin film transistor according to claim 11, further comprising an etch stop layer provided above the active layer, wherein the source and the drain are provided above the etch stop layer, and electrically connected to the active layer through via holes penetrating through the etch stop layer at the left side and the right side of the active layer, respectively.

13. The thin film transistor according to claim 1, further comprising a source, a drain, a gate, a gate insulating layer and a passivation layer, wherein the source and the drain are electrically connected to the active layer at a left side and a right side of the active layer, respectively, the gate is located above the active layer, the gate insulating layer is provided between the gate and the active layer, and the passivation layer covers the gate.

14. The thin film transistor according to claim 13, further comprising an etch stop layer provided above the active layer, wherein the source and the drain are provided above the etch stop layer, and electrically connected to the active layer through via holes penetrating through the etch stop layer at the left side and the right side of the active layer, respectively.

15. The thin film transistor according to claim 1, wherein
the active layer comprises a semiconductor region and two conductive regions at a left side and a right side of the semiconductor region, respectively, the conductive regions are formed by processing materials for forming the active layer with plasma, the thin film transistor comprises a source, a drain, a gate, a gate insulating layer and an interlayer insulating layer, the gate insulating layer is provided on the semiconductor region, the gate is provided on the gate insulating layer, the interlayer insulating layer covers the gate and the active layer, and the source and the drain are located above the two conductive regions and electrically connected to the conductive regions through via holes penetrating through the interlayer insulating layer, respectively.

16. The thin film transistor according to claim 15, further comprising a passivation layer covering the source, the drain and the interlayer insulating layer, and a pixel electrode electrically connected to the drain through a via hole penetrating through the passivation layer.

17. An array substrate, wherein the array substrate is divided into a plurality of display units, and each of the display units is provided with the thin film transistor according to claim 1.

18. A manufacturing method of the array substrate according to claim 17, comprising a step for forming the active layer, wherein the step for forming the active layer comprises steps for forming the semiconductor layers and steps for forming each of the insulating layers between every two adjacent semiconductor layers.

19. The manufacturing method according to claim 18, wherein the semiconductor layers and each of the insulating layers between every two adjacent semiconductor layers are formed by sputtering processes in a single vacuum environment.

20. A display device, comprising the array substrate according to claim 17.
